(19) United States
(12) Patent Application Publication
(10) Pub. No.: US 2025/0203833 A1
(43) Pub. Date: Jun. 19, 2025

(54) UNIT CELL OF FLEXIBLE AND THIN METAMATERIAL ABSORBER FOR 5.8 GHZ AND 10 GHZ WITH OPERATING BANDWIDTH AND METAMATERIAL ABSORBER INCLUDING THE SAME

(71) Applicant: IUCF-HYU (INDUSTRY-UNIVERSITY COOPERATION FOUNDATION HANYANG UNIVERSITY), Seoul (KR)

(72) Inventors: Young Pak LEE, Seoul (KR); Haiyu ZHENG, Chuncheon-si (KR)

(73) Assignee: IUCF-HYU (INDUSTRY-UNIVERSITY COOPERATION FOUNDATION HANYANG UNIVERSITY), Seoul (KR)

(21) Appl. No.: 18/688,135

(22) PCT Filed: Jul. 4, 2022
(86) PCT No.: PCT/KR2022/009575

§ 371 Date: Feb. 29, 2024

(30) Foreign Application Priority Data
Sep. 1, 2021 (KR) 10-2021-0116350
Dec. 8, 2021 (KR) 10-2021-0174373

(51) Int. Cl. H05K 9/00

(52) U.S. Cl. CPC H05K 9/0081

(57) ABSTRACT

A unit cell of a metamaterial absorber may be an electromagnetic wave absorber for a 5.8 GHz band or 10 GHz band. The unit cell of the metamaterial absorber may include a first metal layer including at least one concentric circular ring-shaped conductor pattern, a first intermediate layer disposed on the lower surface of the first metal layer and composed of polyimide, a resistive layer disposed on the lower surface of the first intermediate layer, a second intermediate layer disposed on the lower surface of the resistive layer and composed of polyimide, and a second metal layer disposed on the lower surface of the second intermediate layer. The resistive layer may increase the operating bandwidth of an operating frequency. The thickness of the resistive layer may be 0.05 mm to 0.15 mm. The sheet resistance of the resistive layer may be 530 Ω·sq⁻¹ to 550 Ω·sq⁻¹.

### CROSS-REFERENCE TO RELATED APPLICATIONS

This application is a National Stage Entry of PCT International Application No. PCT/KR2022/009575, which was filed on Jul. 4, 2022, and claims priority to Korean Patent Application No. 10-2021-0116350, filed on Sep. 1, 2021, and Korean Patent Application No. 10-2021-0174373, filed on Dec. 8, 2021, in the Korean Intellectual Property Office, the disclosures of each of which are incorporated herein by reference.

### TECHNICAL FIELD

The present invention relates to a metamaterial absorber, and more particularly, to a unit cell of a metamaterial absorber that is flexible and thin and has an operating bandwidth at 5.8 GHz and 10 GHz and a metamaterial absorber including the same.

### BACKGROUND ART

A conventional electromagnetic wave absorber is a device that greatly reduces reflected or transmitted electromagnetic waves by absorbing electromagnetic waves incident on the surface and consuming the electromagnetic waves as heat, and is used for purposes such as blocking electromagnetic waves. Generally, electromagnetic wave absorbers are mainly based on mixed materials such as ferrite materials. However, these electromagnetic wave absorbers have the disadvantages of being bulky, heavy, and expensive. Therefore, recently, electromagnetic wave absorbers using metamaterials have been proposed.

A metamaterial is an artificially designed material that includes both electric and magnetic elements to have properties not found in nature, and has the ability to easily absorb electromagnetic waves. That is, a metamaterial absorber is an electromagnetic wave absorber implemented using a metamaterial with a high electromagnetic wave absorption rate.

However, conventional metamaterial absorbers have a high absorption rate for electromagnetic waves incident perpendicularly, but have a low absorption rate for electromagnetic waves incident at other angles. In addition, when electromagnetic waves are incident at a large inclination angle, the conventional metamaterial absorbers have a low absorption rate.

In addition, the operating frequency of the conventional metamaterial absorber is limited to a specific frequency, so the conventional metamaterial absorber has no operating bandwidth or the operating bandwidth thereof is very narrow. Accordingly, the electromagnetic wave absorption rate of the metamaterial absorber has a limit in that the electromagnetic wave absorption rate remain high only at certain frequencies in the form of a single peak.

In addition, the conventional metamaterial absorbers have limitations in that the conventional metamaterial absorbers are inflexible, thick, and have relatively high manufacturing costs.

### DISCLOSURE

### Technical Problem

Therefore, the present invention has been made in view of the above problems, and it is one object of the present invention to provide a unit cell of a metamaterial absorber for 5.8 GHz and 10 GHz that maintains a constant electromagnetic wave absorption rate even when the incidence angle of incident electromagnetic waves changes.

It is another object of the present invention to provide a unit cell of a metamaterial absorber for 5.8 GHz and 10 GHz that has an operating bandwidth with a constant operating frequency and maintains a constant electromagnetic wave absorption rate within an operating bandwidth range.

It is yet another object of the present invention to provide a flexible, thin, and relatively inexpensive unit cell of a metamaterial absorber for 5.8 GHz and 10 GHz.

However, the purpose of the present invention is not limited to the above-mentioned purposes, and may be expanded in various ways without departing from the idea and scope of the present invention.

### Technical Solution

In accordance with one aspect of the present invention, provided is a unit cell of a metamaterial absorber, the unit including a first metal layer including at least one concentric circular ring-shaped conductor pattern, a first intermediate layer disposed on a lower surface of the first metal layer and composed of polyimide, a resistive layer disposed on a lower surface of the first intermediate layer, a second intermediate layer disposed on a lower surface of the resistive layer and composed of polyimide, and a second metal layer disposed on a lower surface of the second intermediate layer, wherein the resistive layer increases an operating bandwidth of an operating frequency, a thickness of the resistive layer is 0.05 mm to 0.15 mm, and a sheet resistance of the resistive layer is 530 Ω·sq⁻¹ to 550 Ω·sq⁻¹.

According to one embodiment, the operating bandwidth of the operating frequency may be a center frequency of 5.8 GHz and a band of 5.55 GHz to 6.05 GHz. Within the operating bandwidth range, the unit cell of the metamaterial absorber may have an electromagnetic wave absorption rate of 97% or more for an incidence angle of 45°.

According to one embodiment, the first metal layer may include a first conductor pattern in which a width of a concentric circular ring is 0.3 mm to 0.5 mm and a radius of the concentric circular ring is 5.0 mm to 5.8 mm, and a thickness of the first metal layer may be 30 μm to 40 μm.

According to one embodiment, a horizontal length of the first intermediate layer may be 20 mm to 30 mm, a vertical length of the first intermediate layer may be 20 mm to 30 mm, and a thickness of the first intermediate layer may be 0.1 mm to 0.3 mm.

According to one embodiment, a horizontal length of the resistive layer may be 20 mm to 30 mm, and a vertical length of the resistive layer may be 20 mm to 30 mm.

According to one embodiment, a horizontal length of the second intermediate layer may be 20 mm to 30 mm, a vertical length of the second intermediate layer may be 20 mm to 30 mm, and a thickness of the second intermediate layer may be 0.4 mm to 0.6 mm.

According to one embodiment, a dielectric constant of each of the first and second intermediate layers may be 3.5, and a dielectric loss tangent of each of the first and second intermediate layers may be 0.0027.

According to one embodiment, a horizontal length of the second metal layer may be 20 mm to 30 mm, a vertical length of the second metal layer may be 20 mm to 30 mm, and a thickness of the second metal layer may be 30 μm to 40 μm.

According to one embodiment, the operating bandwidth of the operating frequency may be a center frequency of 10 GHz and a band of 9.5 GHz to 10.5 GHZ. Within the operating bandwidth range, the unit cell of the metamaterial absorber may have an electromagnetic wave absorption rate of 97% or more for an incidence angle of 45°.

According to one embodiment, the first metal layer may include a second conductor pattern. The second conductor pattern may include a first concentric circular ring, and a second concentric circular ring formed to surround the first concentric circular ring, wherein a center of the second concentric circular ring coincides with a center of the first concentric circular ring. A width of each of the first and second concentric circular rings may be 0.3 mm to 0.5 mm. A radius of the first concentric circular ring may be 1.8 mm to 2.0 mm. A radius of the second concentric circular ring may be 3.2 mm to 3.4 mm. A thickness of the first metal layer may be 30 μm to 40 μm.

According to one embodiment, a horizontal length of the first intermediate layer may be 10 mm to 20 mm, a vertical length of the first intermediate layer may be 10 mm to 20 mm, and a thickness of the first intermediate layer may be 0.1 mm to 0.3 mm.

According to one embodiment, a horizontal length of the resistive layer may be 10 mm to 20 mm, and a vertical length of the resistive layer may be 10 mm to 20 mm.

According to one embodiment, a horizontal length of the second intermediate layer may be 10 mm to 20 mm, a vertical length of the second intermediate layer may be 10 mm to 20 mm, and a thickness of the second intermediate layer may be 0.4 mm to 0.6 mm.

According to one embodiment, a dielectric constant of each of the first and second intermediate layers may be 3.5, and a dielectric loss tangent of each of the first and second intermediate layers may be 0.0027.

According to one embodiment, a horizontal length of the second metal layer may be 10 mm to 20 mm, a vertical length of the second metal layer may be 10 mm to 20 mm, and a thickness of the second metal layer may be 30 μm to 40 μm.

In accordance with another aspect of the present invention, provided is a metamaterial absorber including a plurality of unit cells, wherein the unit cells are arranged on the same plane to form a flat structure, and each of the unit cells includes a first metal layer including at least one concentric circular ring-shaped conductor pattern, a first intermediate layer disposed on a lower surface of the first metal layer and composed of polyimide, a resistive layer disposed on a lower surface of the first intermediate layer, a second intermediate layer disposed on a lower surface of the resistive layer and composed of polyimide, and a second metal layer disposed on a lower surface of the second intermediate layer, wherein the resistive layer increases an operating bandwidth of an operating frequency, a thickness of the resistive layer is 0.05 mm to 0.15 mm, and a sheet resistance of the resistive layer is 530 Ω·sq⁻¹ to 550 Ωsq⁻¹.

### Advantageous Effects

A unit cell of a metamaterial absorber according to the present invention and the metamaterial absorber can maintain a constant electromagnetic wave absorption rate even when the incidence angle of incident electromagnetic waves changes.

In addition, the unit cell of the metamaterial absorber according to the present invention and the metamaterial absorber can have an operating bandwidth with a constant operating frequency and maintain a constant electromagnetic wave absorption rate within an operating bandwidth range.

In addition, the unit cell of the metamaterial absorber according to the present invention and the metamaterial absorber can be flexible and thin, and can be manufactured at relatively low cost.

Accordingly, the unit cell of the metamaterial absorber and the metamaterial absorber can maximize the efficiency of absorbing electromagnetic waves.

For example, when the unit cell of the metamaterial absorber according to the present invention and the metamaterial absorber are used in an automatic toll collection system such as High-pass in a 5.8 GHz band, deterioration in performance and malfunction of information and communication devices due to multiple signals reflected from the ceilings and pillars of buildings around the automatic toll collection system are minimized, thereby ensuring smooth passability of the automatic toll collection system.

For example, when the unit cell of the metamaterial absorber according to the present invention and the metamaterial absorber are used in a naval ship in a 10 GHz band, since radar false targets caused by waves reflected from masts or piers around the naval ship are reduced, the radar performance of the naval ship can be improved.

However, the effects of the present invention are not limited to the effects described above, and may be expanded in various ways without departing from the idea and scope of the present invention.

### DESCRIPTION OF DRAWINGS

FIG. 1 is a perspective view showing a unit cell of a metamaterial absorber of the present invention.

FIG. 2 is a cross-sectional view showing the laminated structure of the unit cell of the metamaterial absorber of FIG. 1.

FIG. 3 is a front view of a unit cell of a metamaterial absorber for 5.8 GHz according to embodiments of the present invention.

FIG. 4 is a perspective view of the unit cell of the metamaterial absorber for 5.8 GHz of FIG. 3.

FIG. 5 is a diagram showing a first intermediate layer separated from the perspective view of FIG. 4.

FIG. 6 is a diagram showing a resistive layer separated from the perspective view of FIG. 4.

FIG. 7 is a diagram showing a second intermediate layer separated from the perspective view of FIG. 4.

FIG. 8 is a diagram showing a second metal layer separated from the perspective view of FIG. 4.

FIG. 9 is a graph showing electromagnetic wave absorption rates depending on incidence angles in a band of 5.55 GHz to 6.05 GHz when electromagnetic waves polarized in a TE mode are incident on the unit cell of the metamaterial absorber for 5.8 GHz of FIG. 3.

FIG. 10 is a graph showing electromagnetic wave absorption rates depending on incidence angles in a band of 5.55 GHz to 6.05 GHz when electromagnetic waves polarized in a TM mode are incident on the unit cell of the metamaterial absorber for 5.8 GHz of FIG. 3.

FIG. 11 is a front view of a unit cell of a metamaterial absorber for 10 GHz according to embodiments of the present invention.

FIG. 12 is a perspective view of the unit cell of the metamaterial absorber for 10 GHz of FIG. 11.

FIG. 13 is a diagram showing a first intermediate layer separated from the perspective view of FIG. 12.

FIG. 14 is a diagram showing a resistive layer separated from the perspective view of FIG. 12.

FIG. 15 is a diagram showing a second intermediate layer separated from the perspective view of FIG. 12.

FIG. 16 is a diagram showing a second metal layer separated from the perspective view of FIG. 12.

FIG. 17 is a graph showing electromagnetic wave absorption rates depending on incidence angles in a band of 9.5 GHz to 10.5 GHz when electromagnetic waves polarized in a TE mode are incident on the unit cell of the metamaterial absorber for 10 GHz of FIG. 11.

FIG. 18 is a graph showing electromagnetic wave absorption rates depending on incidence angles in a band of 9.5 GHz to 10.5 GHz when electromagnetic waves polarized in a TM mode are incident on the unit cell of the metamaterial absorber for 10 GHz of FIG. 11.

FIG. 19 is a diagram showing an example of a metamaterial absorber in which the unit cells of the metamaterial absorber of FIG. 1 are arranged on the same plane.

FIG. 20 is a flowchart showing the operation of the metamaterial absorber of FIG. 19 to absorb electromagnetic waves.

### BEST MODE

Hereinafter, preferred embodiments of the present invention will be described in detail with reference to the accompanying drawings.

However, it should be understood that the present invention is not limited to the embodiments according to the concept of the present invention, but includes changes, equivalents, or alternatives falling within the spirit and scope of the present invention.

In addition, in the following description of the present invention, a detailed description of known functions and configurations incorporated herein will be omitted when it may make the subject matter of the present invention unclear.

The terms used in the specification are defined in consideration of functions used in the present invention, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), the first element may be directly connected to the second element or may be connected to the second element via an intervening element (e.g., third).

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

Terms, such as “unit” or “module”, etc., should be understood as a unit that processes at least one function or operation and that may be embodied in a hardware manner, a software manner, or a combination of the hardware manner and the software manner.

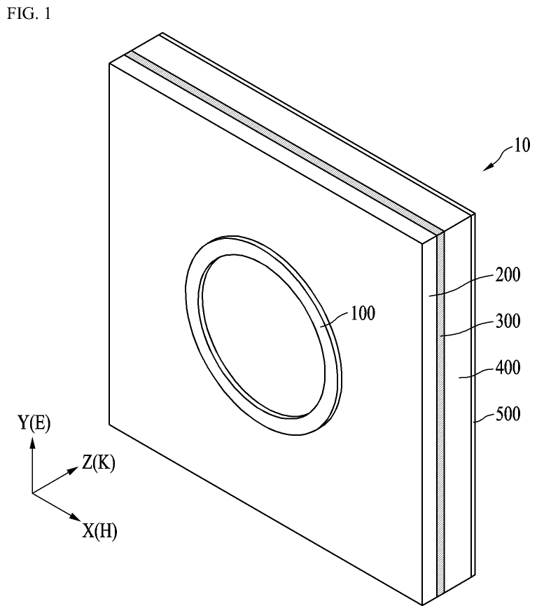

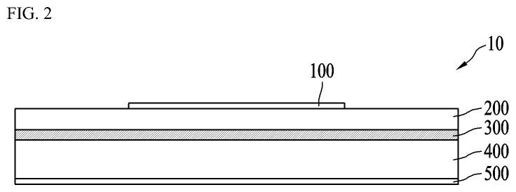

FIG. 1 is a perspective view showing a unit cell 10 of a metamaterial absorber of the present invention, and FIG. 2 is a cross-sectional view showing the laminated structure of the unit cell 10 of the metamaterial absorber of FIG. 1.

Referring to FIGS. 1 and 2, the unit cell 10 of the metamaterial absorber of the present invention may include a first metal layer 100, a first intermediate layer 200, a resistive layer 300, a second intermediate layer 400, and a second metal layer 500.

For example, as shown in FIG. 2, the unit cell 10 of the metamaterial absorber may have a five-layer structure in which the first metal layer 100, the first intermediate layer 200, the resistive layer 300, the second intermediate layer 400, and the second metal layer 500 are laminated.

Specifically, the unit cell 10 of the metamaterial absorber may include the first metal layer 100 including at least one concentric circular ring-shaped conductor pattern, the first intermediate layer 200 disposed on the lower surface of the first metal layer 100 and composed of polyimide, the resistive layer 300 disposed on the lower surface of the first intermediate layer 200, the second intermediate layer 400 disposed on the lower surface of the resistive layer 300 and composed of polyimide, and the second metal layer 500 disposed on the lower surface of the second intermediate layer 400.

The operating frequency of a conventional metamaterial absorber is limited to a specific frequency, so the conventional metamaterial absorber has no operating bandwidth or has a very narrow operating bandwidth. Accordingly, the electromagnetic wave absorption rate of the conventional metamaterial absorber has a limit of being maintained high only at certain frequencies in the form of a single peak.

The unit cell 10 of the metamaterial absorber of the present invention may have an operating bandwidth with a constant operating frequency and maintain a constant electromagnetic wave absorption rate within an operating bandwidth range.

Specifically, the resistive layer 300 may increase the operating bandwidth of operating frequency for electromagnetic wave absorption. For this purpose, the thickness of the resistive layer 300 may be 0.05 mm to 0.15 mm, and the sheet resistance of the resistive layer 300 may be 530 Ω·sq⁻¹ to 550 Ω·sq⁻¹.

In addition, the unit cell 10 of the metamaterial absorber of the present invention may maintain a constant electromagnetic wave absorption rate even when the incidence angle of incident electromagnetic waves changes.

In addition, the unit cell 10 of the metamaterial absorber according to the present invention may be flexible and thin, and may be manufactured at relatively low cost.

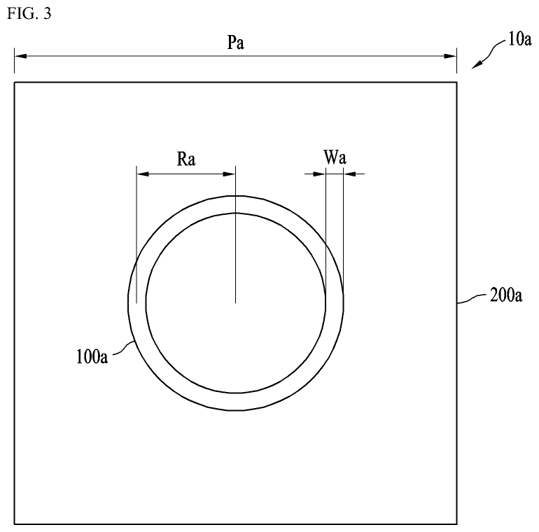

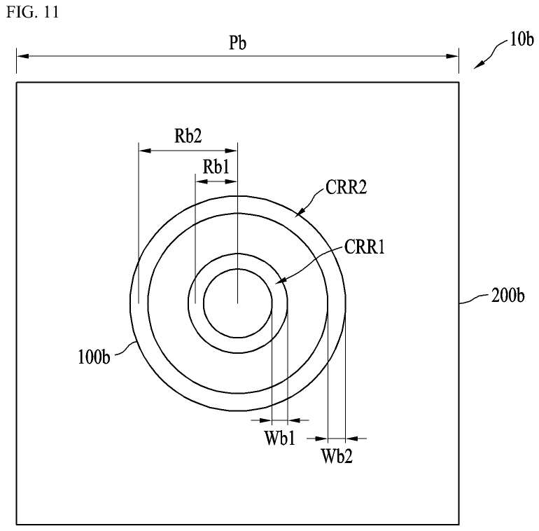

Hereinafter, an embodiment of a unit cell 10a of a metamaterial absorber for 5.8 GHz of the present invention will be described with reference to FIGS. 3 to 10, and an embodiment of a unit cell 10b of a metamaterial absorber for 10 GHz of the present invention will be described with reference to FIGS. 11 to 18.

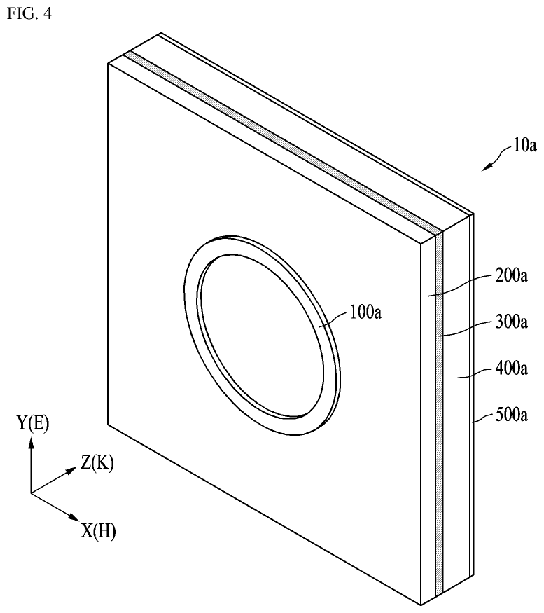

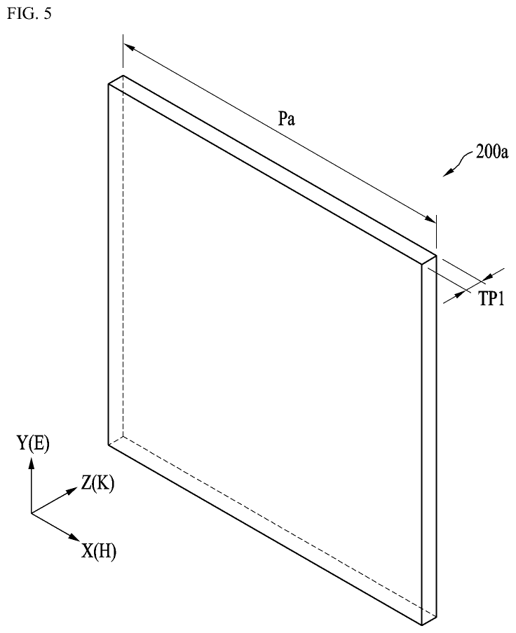

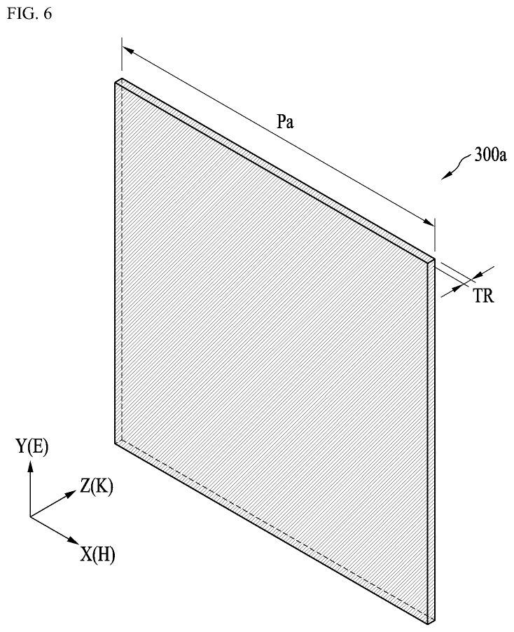

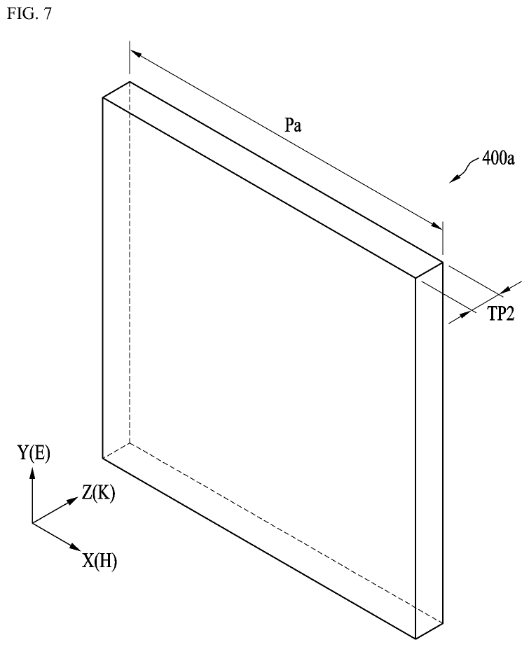

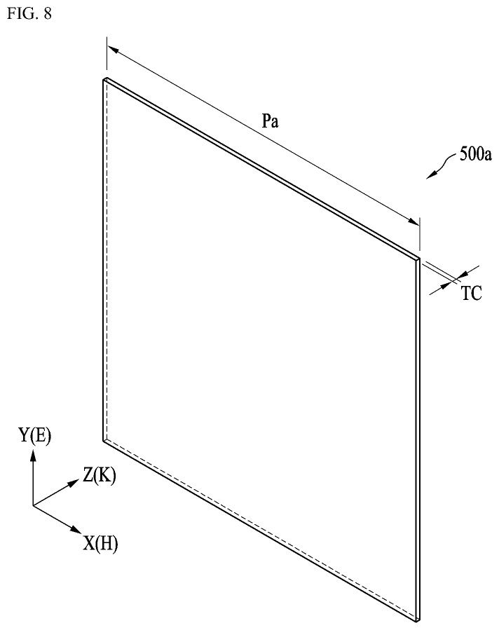

FIG. 3 is a front view of the unit cell 10a of the metamaterial absorber for 5.8 GHz according to embodiments of the present invention, FIG. 4 is a perspective view of the unit cell 10a of the metamaterial absorber for 5.8 GHz of FIG. 3, FIG. 5 is a diagram showing a first intermediate layer 200a separated from the perspective view of FIG. 4, FIG. 6 is a diagram showing a resistive layer 300a separated from the perspective view of FIG. 4, FIG. 7 is a diagram showing a second intermediate layer 400a separated from the perspective view of FIG. 4, and FIG. 8 is a diagram showing a second metal layer 500a separated from the perspective view of FIG. 4.

Referring to FIGS. 3 and 4, since the unit cell 10a of the metamaterial absorber of the present invention has an optimized size, shape, and conductor pattern, the electromagnetic wave absorption rate may be maximized in the 5.8 GHz band.

The operating frequency of the unit cell 10a of the metamaterial absorber may have a constant operating bandwidth. For example, the operating bandwidth of the operating frequency may be a center frequency of 5.8 GHz and a band of 5.55 GHz to 6.05 GHz.

The unit cell 10a of the metamaterial absorber may have an electromagnetic wave absorption rate of 97% or more for an incidence angle of 45° within the operating bandwidth range.

Specifically, the unit cell 10a of the metamaterial absorber may include a first metal layer 100a including a first conductor pattern in the shape of a concentric circular ring, the first intermediate layer 200a disposed on the lower surface of the first metal layer 100a and composed of polyimide, the resistive layer 300a disposed on the lower surface of the first intermediate layer 200a, the second intermediate layer 400a disposed on the lower surface of the resistive layer 300a and composed of polyimide, and the second metal layer 500a disposed on the lower surface of the second intermediate layer 400a.

Depending on the design of the conductor pattern of the first metal layer 100a, the metamaterial absorber unit cell may minimize the reflection of electromagnetic waves in the 5.8 GHz band. That is, since the impedance of the atmosphere is 1, the conductor pattern may be designed so that the impedance of the entire conductor pattern is 1 in the 5.8 GHz band.

For example, the first metal layer 100a may include a first conductor pattern in which the width (Wa) of the concentric circular ring is 0.3 mm to 0.5 mm and the radius (Ra) of the concentric circular ring is 5.0 mm to 5.8 mm. The thickness of the first metal layer 100a may be 30 μm to 40 μm.

Referring to FIGS. 4 and 5, the first intermediate layer 200a may be disposed on the lower surface of the first metal layer 100a and may be composed of polyimide.

For example, the horizontal length (Pa) of the first intermediate layer 200a may be 20 mm to 30 mm. The vertical length of the first intermediate layer 200a may be 20 mm to 30 mm. The thickness (TP1) of the first intermediate layer 200a may be 0.1 mm to 0.3 mm.

Referring to FIGS. 4 and 6, the resistive layer 300a may be disposed on the lower surface of the first intermediate layer 200a. By having a constant sheet resistance, the resistive layer 300a may increase the operating bandwidth of the operating frequency for electromagnetic wave absorption. For example, the sheet resistance of the resistive layer 300a may be 530 Ω·sq⁻¹ to 550 Ω·sq⁻¹.

The thickness (TR) of the resistive layer 300a may be 0.05 mm to 0.15 mm. For example, to minimize the effect on the flexibility of the unit cell 10a of the metamaterial absorber, the resistive layer 300a may be designed to have a thickness of 0.1 mm.

The horizontal length (Pa) of the resistive layer 300a may be 20 mm to 30 mm. The vertical length of the resistive layer 300a may be 20 mm to 30 mm.

According to the configuration of the resistive layer 300a, the unit cell 10a of the metamaterial absorber may maintain an operating frequency at which electromagnetic waves are absorbed at a 5.8 GHz±0.25 GHz band even when an incidence angle changes.

Referring to FIGS. 4 and 7, the second intermediate layer 400a may be disposed on the lower surface of the resistive layer 300a and may be composed of polyimide.

For example, the horizontal length (Pa) of the second intermediate layer 400a may be 20 mm to 30 mm. The vertical length of the second intermediate layer 400a may be 20 mm to 30 mm. The thickness (TP2) of the second intermediate layer 400a may be 0.4 mm to 0.6 mm.

By including the first and second intermediate layers 200a and 400a composed of polyimide, the unit cell 10a of the metamaterial absorber may be flexible and thin, and the unit cell 10a may be manufactured at relatively low cost.

The first and second intermediate layers 200a and 400a may electrically confine and store electromagnetic waves incident on the unit cell 10a of the metamaterial absorber and attenuate electromagnetic waves in a 5.8 GHz band. For this purpose, the size of the first and second intermediate layers 200a and 400a included in the unit cell 10a of the metamaterial absorber may be 25×25 mm².

For example, the dielectric constant of the first and second intermediate layers 200a and 400a may be 3.5. The dielectric loss tangent of the first and second intermediate layers 200a and 400a may be 0.0027.

According to the configuration of the first and second intermediate layers 200a and 400a, the unit cell 10a of the metamaterial absorber may have an absorption rate of 99% or more for vertically incident electromagnetic waves in a 5.8 GHz band.

Referring to FIGS. 4 and 8, the second metal layer 500a may be disposed on the lower surface of the second intermediate layer 400a. The second metal layer 500a may perform the function of preventing electromagnetic waves entering the unit cell 10a of the metamaterial absorber from escaping. The second metal layer 500a may be formed of copper.

For example, the horizontal length (Pa) of the second metal layer 500a may be 20 mm to 30 mm. The vertical length of the second metal layer 500a may be 20 mm to 30 mm. The thickness (TC) of the second metal layer 500a may be 30 μm to 40 μm.

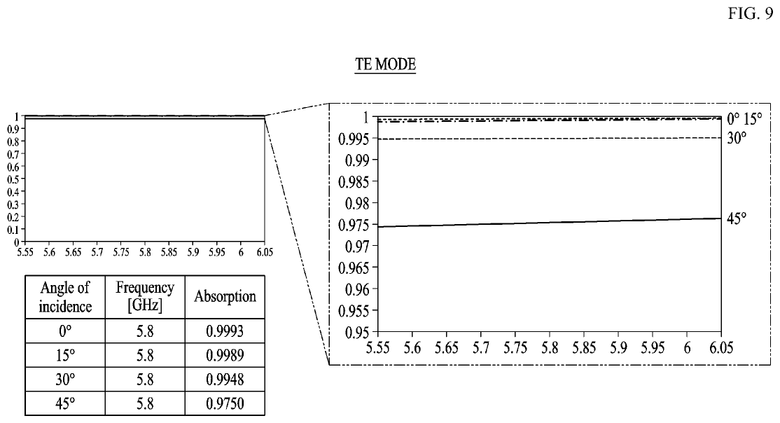

FIG. 9 is a graph showing electromagnetic wave absorption rates depending on incidence angles in a band of 5.55 GHz to 6.05 GHz when electromagnetic waves polarized in a TE mode are incident on the unit cell 10a of the metamaterial absorber for 5.8 GHz of FIG. 3.

As shown in FIG. 9, the unit cell 10a of the metamaterial absorber may maintain an electromagnetic wave absorption rate of 97% or more for electromagnetic waves polarized in a TE mode even when an incidence angle changes in a band of 5.55 GHz to 6.05 GHz.

When electromagnetic waves polarized in a TE mode are incident perpendicularly (or incident at) 0°, the unit cell 10a of the metamaterial absorber exhibits an electromagnetic wave absorption rate of 99.93% or more in a band of 5.55 GHz to 6.05 GHz.

When electromagnetic waves polarized in a TE mode are incident at 15°, the unit cell 10a of the metamaterial absorber exhibits an electromagnetic wave absorption rate of 99.89% or more in a band of 5.55 GHz to 6.05 GHz.

When electromagnetic waves polarized in a TE mode are incident at 30°, the unit cell 10a of the metamaterial absorber exhibits an electromagnetic wave absorption rate of 99.48% or more in a band of 5.55 GHz to 6.05 GHz.

When electromagnetic waves polarized in a TE mode are incident at 45°, the unit cell 10a of the metamaterial absorber exhibits an electromagnetic wave absorption rate of 97.50% or more in a band of 5.55 GHz to 6.05 GHz.

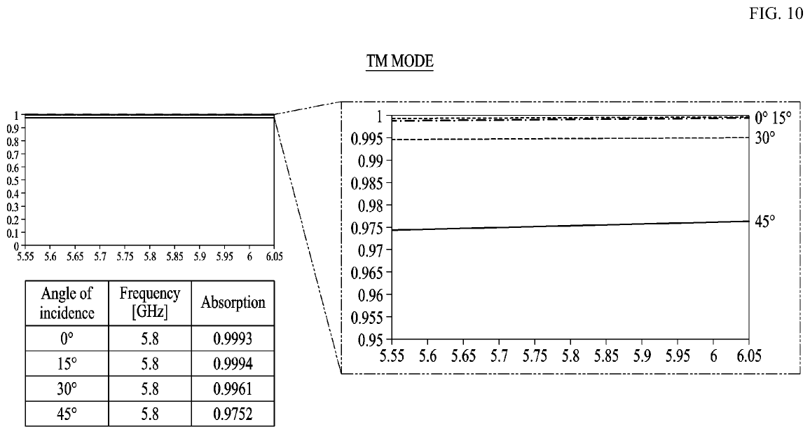

FIG. 10 is a graph showing electromagnetic wave absorption rates depending on incidence angles in a band of 5.55 GHz to 6.05 GHz when electromagnetic waves polarized in a TM mode are incident on the unit cell 10a of the metamaterial absorber for 5.8 GHz of FIG. 3.

As shown in FIG. 10, the unit cell 10a of the metamaterial absorber may maintain an electromagnetic wave absorption rate of 97% or more for electromagnetic waves polarized in a TM mode even when an incidence angle changes in a band of 5.55 GHz to 6.05 GHz.

When electromagnetic waves polarized in a TM mode are incident perpendicularly (or incident at) 0°, the unit cell 10a of the metamaterial absorber exhibits an electromagnetic wave absorption rate of 99.93% or more in a band of 5.55 GHz to 6.05 GHz.

When electromagnetic waves polarized in a TM mode are incident at 15°, the unit cell 10a of the metamaterial absorber exhibits an electromagnetic wave absorption rate of 99.94% or more in a band of 5.55 GHz to 6.05 GHz.

When electromagnetic waves polarized in a TM mode are incident at 30°, the unit cell 10a of the metamaterial absorber exhibits an electromagnetic wave absorption rate of 99.61% or more in a band of 5.55 GHz to 6.05 GHz.

When electromagnetic waves polarized in a TM mode are incident at 45°, the unit cell 10a of the metamaterial absorber exhibits an electromagnetic wave absorption rate of 97.52% or more in a band of 5.55 GHz to 6.05 GHz.

As described above, the unit cell 10a of the metamaterial absorber according to the present invention may maintain a constant electromagnetic wave absorption rate in a band of 5.8 GHz even when the incidence angle of incident electromagnetic waves changes. In addition, in the unit cell 10a of the metamaterial absorber according to the present invention, the operating frequency may have an operating bandwidth of 5.8 GHz±0.25 GHz, and the electromagnetic wave absorption rate may be maintained constant in the operating bandwidth range. In addition, the unit cell 10a of the metamaterial absorber according to the present invention may be flexible and thin, and may be manufactured at relatively low cost. Accordingly, the unit cell 10a of the metamaterial absorber may maximize the efficiency of absorbing electromagnetic waves.

For example, when the unit cell 10a of the metamaterial absorber according to the present invention is used in an automatic toll collection system such as High-pass in the 5.8 GHz band, deterioration in performance and malfunction of information and communication devices due to multiple signals reflected from the ceilings and pillars of buildings around the automatic toll collection system are minimized, thereby ensuring smooth passability of the automatic toll collection system.

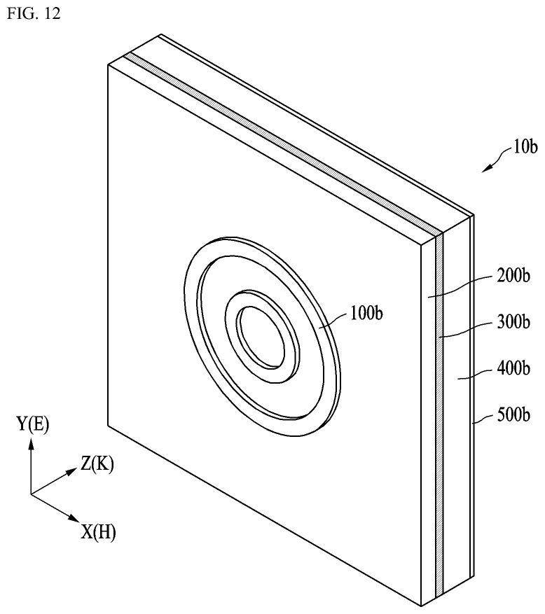

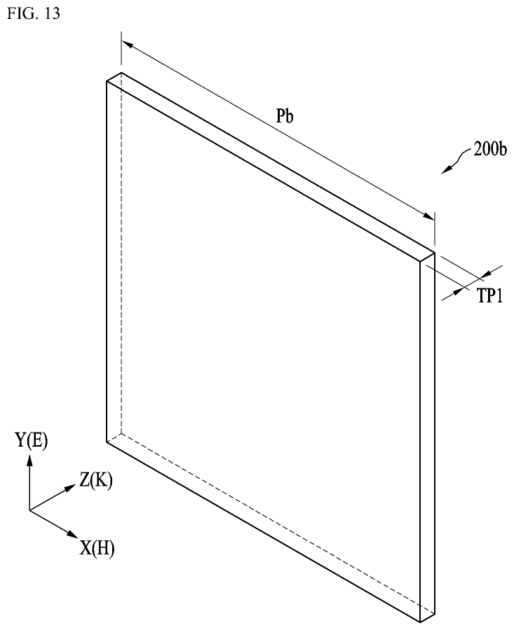

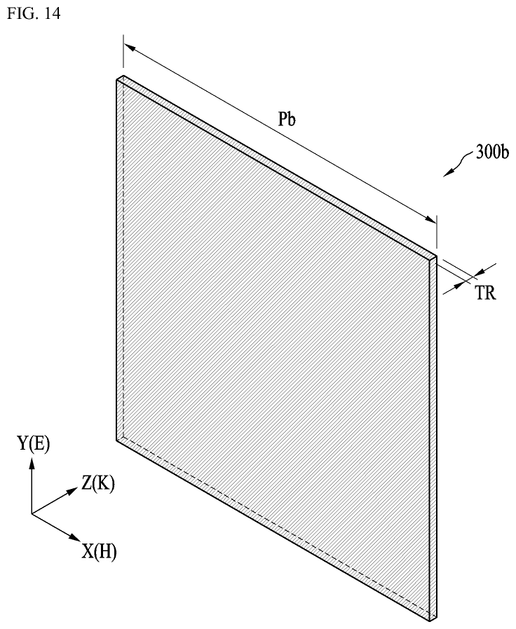

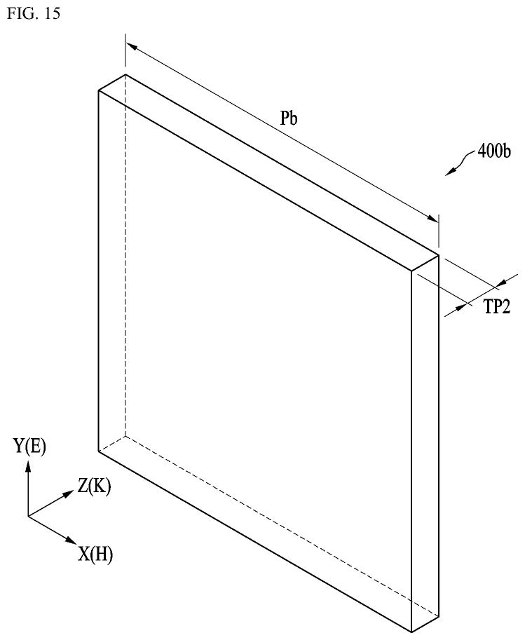

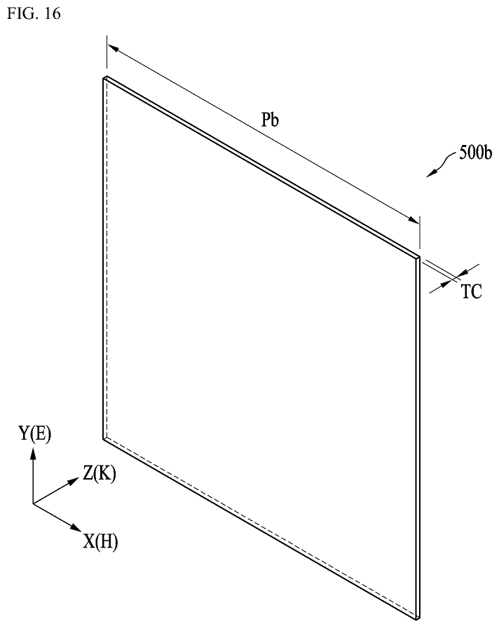

FIG. 11 is a front view of a unit cell 10b of a metamaterial absorber for 10 GHz according to embodiments of the present invention, FIG. 12 is a perspective view of the unit cell 10b of the metamaterial absorber for 10 GHz of FIG. 11, FIG. 13 is a diagram showing a first intermediate layer 200b separated from the perspective view of FIG. 12, FIG. 14 is a diagram showing a resistive layer 300b separated from the perspective view of FIG. 12, FIG. 15 is a diagram showing a second intermediate layer 400b separated from the perspective view of FIG. 12, and FIG. 16 is a diagram showing a second metal layer 500b separated from the perspective view of FIG. 12.

Referring to FIGS. 11 and 12, since the unit cell 10b of the metamaterial absorber of the present invention has an optimized size, shape, and conductor pattern, the electromagnetic wave absorption rate in a band of 10 GHz may be maximized.

The operating frequency of the unit cell 10b of the metamaterial absorber may have a constant operating bandwidth. For example, the operating bandwidth of the operating frequency may be a center frequency of 10 GHz and a band of 9.5 GHz to 10.5 GHz.

The unit cell 10b of the metamaterial absorber may have an electromagnetic wave absorption rate of 97% or more for an incidence angle of 45° within the operating bandwidth range.

Specifically, the unit cell 10b of the metamaterial absorber may include a first metal layer 100b including a second conductor pattern including two concentric circular ring shapes, the first intermediate layer 200b disposed on the lower surface of the first metal layer 100b and composed of polyimide, the resistive layer 300b disposed on the lower surface of the first intermediate layer 200b, the second intermediate layer 400b disposed on the lower surface of the resistive layer 300b and composed of polyimide, and the second metal layer 500b disposed on the lower surface of the second intermediate layer 400b.

Depending on the design of the conductor pattern of the first metal layer 100b, the metamaterial absorber unit cell may minimize the reflection of electromagnetic waves in a band of 10 GHz. That is, since the impedance of the atmosphere is 1, the conductor pattern may be designed so that the impedance of the entire conductor pattern is 1 in a band of 10 GHz.

The second conductor pattern may include a first concentric circular ring (CRR1) and a second concentric circular ring (CRR2) formed to surround the first concentric circular ring (CRR1). In this case, the center of second concentric circular ring (CRR2) may coincide with the center of the first concentric circular ring (CRR1).

The width (Wb1) of the first concentric circular ring may be 0.3 mm to 0.5 mm. The width (Wb2) of the second concentric circular ring may be 0.3 mm to 0.5 mm. The radius (Rb1) of the first concentric circular ring may be 1.8 mm to 2.0 mm. The radius (Rb2) of the second concentric circular ring may be 3.2 mm to 3.4 mm. The thickness of the first metal layer 100b may be 30 μm to 40 μm.

Referring to FIGS. 12 and 13, the first intermediate layer 200b may be disposed on the lower surface of the first metal layer 100b and may be composed of polyimide.

For example, the horizontal length (Pa) of the first intermediate layer 200b may be 10 mm to 20 mm. The vertical length of the first intermediate layer 200b may be 10 mm to 20 mm. The thickness (TP1) of the first intermediate layer 200b may be 0.1 mm to 0.3 mm.

Referring to FIGS. 12 and 14, the resistive layer 300b may be disposed on the lower surface of the first intermediate layer 200b. By having a constant sheet resistance, the resistive layer 300b may increase the operating bandwidth of the operating frequency for electromagnetic wave absorption. For example, the sheet resistance of the resistive layer 300b may be 530 Ω·sq⁻¹ to 550 Ω·sq⁻¹.

The thickness (TR) of the resistive layer 300b may be 0.05 mm to 0.15 mm. For example, the resistive layer 300b may be designed to be 0.1 mm thick to minimize the effect on the flexibility of the unit cell 10b of the metamaterial absorber.

The horizontal length (Pa) of the resistive layer 300b may be 10 mm to 20 mm. The vertical length of the resistive layer 300b may be 10 mm to 20 mm.

According to the configuration of the resistive layer 300b, even when the incidence angle changes, the unit cell 10b of the metamaterial absorber may maintain an operating frequency at which electromagnetic waves are absorbed in a band of 10 GHz±0.5 GHz.

Referring to FIGS. 12 and 15, the second intermediate layer 400b may be disposed on the lower surface of the resistive layer 300b and may be composed of polyimide.

For example, the horizontal length (Pa) of the second intermediate layer 400b may be 10 mm to 20 mm. The vertical length of the second intermediate layer 400b may be 10 mm to 20 mm. The thickness (TP2) of the second intermediate layer 400b may be 0.4 mm to 0.6 mm.

By including the first and second intermediate layers 200b and 400b composed of polyimide, the unit cell 10b of the metamaterial absorber may be flexible and thin, and may be manufactured at relatively low cost.

The first and second intermediate layers 200b and 400b may electrically confine and store electromagnetic waves incident on the unit cell 10b of the metamaterial absorber, and may attenuate electromagnetic waves in a band of 10 GHz. For this purpose, the size of each of the first and second intermediate layers 200b and 400b included in the unit cell 10b of the metamaterial absorber may be 15×15 mm².

For example, the dielectric constant of each of the first and second intermediate layers 200b and 400b may be 3.5. The dielectric loss tangent of each of the first and second intermediate layers 200b and 400b may be 0.0027.

According to the configuration of the first and second intermediate layers 200b and 400b, the unit cell 10b of the metamaterial absorber may have an absorption rate of 99% or more for vertically incident electromagnetic waves in a band of 10 GHz.

Referring to FIGS. 12 and 16, the second metal layer 500b may be disposed on the lower surface of the second intermediate layer 400b. The second metal layer 500b may perform the function of preventing electromagnetic waves entering the unit cell 10b of the metamaterial absorber from escaping. The second metal layer 500b may be formed of copper.

For example, the horizontal length (Pa) of the second metal layer 500b may be 10 mm to 20 mm. The vertical length of the second metal layer 500b may be 10 mm to 20 mm. The thickness (TC) of the second metal layer 500b may be 30 μm to 40 μm.

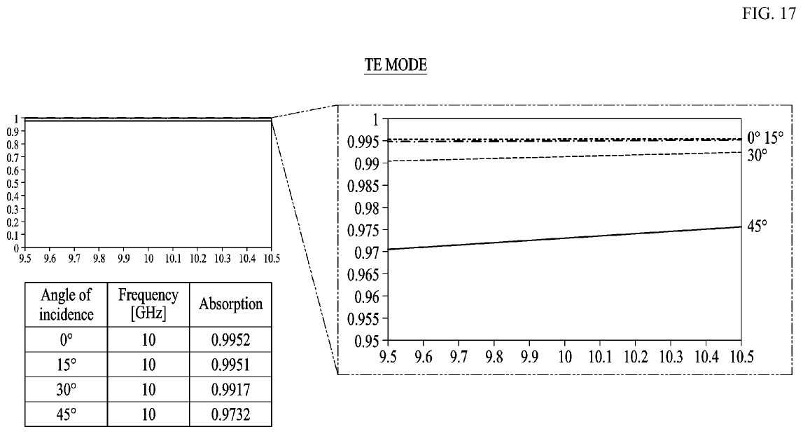

FIG. 17 is a graph showing electromagnetic wave absorption rates depending on incidence angles in a band of 9.5 GHz to 10.5 GHz when electromagnetic waves polarized in a TE mode are incident on the unit cell 10b of the metamaterial absorber for 10 GHz of FIG. 11.

As shown in FIG. 17, even when the incidence angle changes in a band of 9.5 GHz to 10.5 GHz, the unit cell 10b of the metamaterial absorber may maintain an electromagnetic wave absorption rate of 97% or more for electromagnetic waves polarized in a TE mode.

When electromagnetic waves polarized in a TE mode are incident perpendicularly (or incident at) 0°, the unit cell 10b of the metamaterial absorber exhibits an electromagnetic wave absorption rate of 99.52% or more in a band of 9.5 GHz to 10.5 GHz.

When electromagnetic waves polarized in a TE mode are incident at 15°, the unit cell 10b of the metamaterial absorber exhibits an electromagnetic wave absorption rate of 99.51% or more in a band of 9.5 GHz to 10.5 GHz.

When electromagnetic waves polarized in a TE mode are incident at 30°, the unit cell 10b of the metamaterial absorber exhibits an electromagnetic wave absorption rate of 99.17% or more in a band of 9.5 GHz to 10.5 GHz.

When electromagnetic waves polarized in a TE mode are incident at 45°, the unit cell 10b of the metamaterial absorber exhibits an electromagnetic wave absorption rate of 97.32% or more in a band of 9.5 GHz to 10.5 GHz.

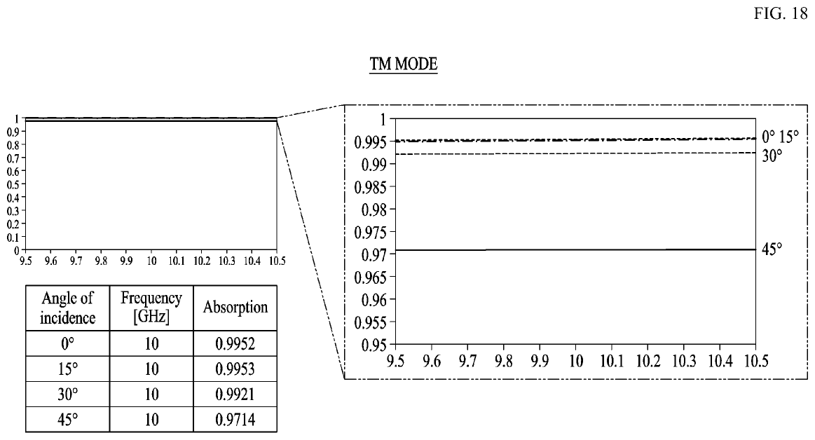

FIG. 18 is a graph showing electromagnetic wave absorption rates depending on incidence angles in a band of 9.5 GHz to 10.5 GHz when electromagnetic waves polarized in a TM mode are incident on the unit cell 10b of the metamaterial absorber for 10 GHz of FIG. 11.

As shown in FIG. 10, even when the incidence angle changes in a band of 9.5 GHz to 10.5 GHz, the unit cell 10b of the metamaterial absorber may maintain an electromagnetic wave absorption rate of 97% or more for electromagnetic waves polarized in a TM mode.

When electromagnetic waves polarized in a TM mode are incident perpendicularly (or incident at) 0°, the unit cell 10b of the metamaterial absorber exhibits an electromagnetic wave absorption rate of 99.52% or more in a band of 9.5 GHz to 10.5 GHz.

When electromagnetic waves polarized in a TM mode are incident at 15°, the unit cell 10b of the metamaterial absorber exhibits an electromagnetic wave absorption rate of 99.53% or more in a band of 9.5 GHz to 10.5 GHz.

When electromagnetic waves polarized in a TM mode are incident at 30°, the unit cell 10b of the metamaterial absorber exhibits an electromagnetic wave absorption rate of 99.21% or more in a band of 9.5 GHz to 10.5 GHz.

When electromagnetic waves polarized in a TM mode are incident at 45°, the unit cell 10b of the metamaterial absorber exhibits an electromagnetic wave absorption rate of 97.14% or more in a band of 9.5 GHz to 10.5 GHz.

As described above, the unit cell 10b of the metamaterial absorber according to the present invention may maintain a constant electromagnetic wave absorption rate in a band of 10 GHz even when the incidence angle of incident electromagnetic waves changes. In addition, in the unit cell 10b of the metamaterial absorber according to the present invention, the operating frequency may have an operating bandwidth of 10 GHz±0.5 GHz, and the electromagnetic wave absorption rate may be maintained constant in the operating bandwidth range. In addition, the unit cell 10b of the metamaterial absorber according to the present invention may be flexible and thin, and may be manufactured at relatively low cost. Accordingly, the unit cell 10b of the metamaterial absorber may maximize the efficiency of absorbing electromagnetic waves.

For example, when the unit cell 10b of the metamaterial absorber according to the present invention is used in a naval ship in a band of 10 GHz, since radar false targets caused by waves reflected from masts or piers around the naval ship are reduced, the radar performance of the naval ship may be improved.

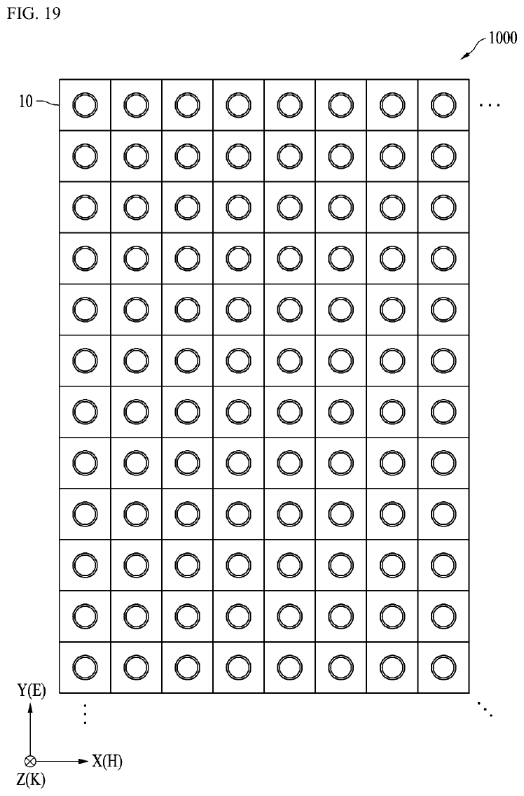

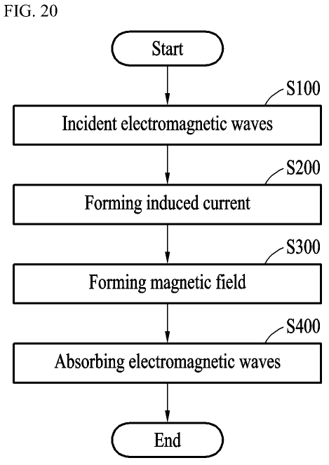

FIG. 19 is a diagram showing an example of a metamaterial absorber 1000 in which the unit cells 10 of the metamaterial absorber of FIG. 1 are arranged on the same plane, and FIG. 20 is a flowchart showing the operation of the metamaterial absorber 1000 of FIG. 19 to absorb electromagnetic waves.

Referring to FIGS. 19 and 20, the metamaterial absorber 1000 may include a plurality of unit cells 10 having a square shape. The unit cells 10 may be arranged on the same plane to form a flat structure to form the metamaterial absorber 1000.

For example, each of the unit cells 10 that make up the metamaterial absorber 1000 may have the same shape and size.

Since the unit cells 10 each absorb electromagnetic waves, the metamaterial absorber 1000 may absorb incident electromagnetic waves over a wide range.

As shown in FIG. 20, when electromagnetic waves are incident (S100), the metamaterial absorber 1000 according to the present invention may form induced current (S200), may form a magnetic field (S300), and may absorb electromagnetic waves (S400).

Here, absorbing electromagnetic waves may mean that the metamaterial absorber 1000 absorbs energy contained in the electromagnetic waves. In addition, electromagnetic wave absorption of the metamaterial absorber 1000 may not be an active operation of the metamaterial absorber 1000 to absorb electromagnetic waves, but may be a passive effect depending on the physical components and electromagnetic characteristics of the metamaterial absorber 1000.

Specifically, electromagnetic waves of a wide band frequency may be incident on the metamaterial absorber 1000 at various incidence angles (S100). When the electromagnetic waves are incident on the metamaterial absorber 1000, induced current may be formed simultaneously in the first and second metal layers 100 and 500 (S200).

An induced magnetic field may be formed in the intermediate layers 200 and 400 by the induced current of the first metal layer 100 and the induced current of the second metal layer 500 (S300). Electromagnetic waves and an induced magnetic field incident on the metamaterial absorber 1000 may magnetically resonate by impedance matching.

As the energy of the electromagnetic waves incident on the metamaterial absorber 1000 is absorbed by magnetic resonance, the metamaterial absorber 1000 may absorb the electromagnetic waves (S400).

Here, the operating frequency of the metamaterial absorber 1000 may be determined depending on the size and shape of the unit cells 10 constituting the metamaterial absorber 1000. Since the size of the induced magnetic field is maximum when the operating frequency is a resonant frequency, the metamaterial absorber 1000 may absorb electromagnetic waves to the maximum at the resonant frequency.

According to one embodiment, each of the unit cells 10 included in the metamaterial absorber 1000 may include the first metal layer 100 including at least one concentric circular ring-shaped conductor pattern, the first intermediate layer 200 disposed on the lower surface of the first metal layer 100 and composed of polyimide, the resistive layer 300 disposed on the lower surface of the first intermediate layer 200, the second intermediate layer 400 disposed on the lower surface of the resistive layer 300 and composed of polyimide, and the second metal layer 500 disposed on the lower surface of the second intermediate layer 400. The resistive layer 300 may increase the operating bandwidth of the operating frequency. The thickness of the resistive layer 300 may be 0.05 mm to 0.15 mm. The sheet resistance of the resistive layer 300 may be 530 Ω·sq⁻¹ to 550 Ω·sq⁻¹.

The metamaterial absorber 1000 according to the present invention may maintain a constant electromagnetic wave absorption rate even when the incidence angle of incident electromagnetic waves changes. In addition, the metamaterial absorber 1000 according to the present invention may have an operating bandwidth with a constant operating frequency and maintain a constant electromagnetic wave absorption rate within an operating bandwidth range. In addition, the metamaterial absorber 1000 according to the present invention may be flexible and thin, and may be manufactured at relatively low cost. Accordingly, the metamaterial absorber 1000 may maximize the efficiency of absorbing electromagnetic waves.

However, since the above matter has been described above, repeated descriptions will be omitted.

Although the present invention has been described with reference to limited embodiments and drawings, it should be understood by those skilled in the art that various changes and modifications may be made therein. For example, the described techniques may be performed in a different order than the described methods, and/or components of the described systems, structures, devices, circuits, etc., may be combined in a manner that is different from the described method, or appropriate results may be achieved even if replaced by other components or equivalents.

Therefore, other embodiments, other examples, and equivalents to the claims are within the scope of the following claims.

[Description of Symbols]

| | |
|---|---|
| 10: UNIT CELL OF METAMATERIAL ABSORBER | 100: FIRST METAL LAYER |
| 200: FIRST INTERMEDIATE LAYER | 300: RESISTIVE LAYER |
| 400: SECOND INTERMEDIATE LAYER | 500: SECOND METAL LAYER |
| 1000: METAMATERIAL ABSORBER | |

1. A unit cell of a metamaterial absorber, comprising:
a first metal layer comprising at least one concentric circular ring-shaped conductor pattern;
a first intermediate layer disposed on a lower surface of the first metal layer and composed of polyimide;
a resistive layer disposed on a lower surface of the first intermediate layer;
a second intermediate layer disposed on a lower surface of the resistive layer and composed of polyimide; and
a second metal layer disposed on a lower surface of the second intermediate layer,
wherein the resistive layer increases an operating bandwidth of an operating frequency,
a thickness of the resistive layer is 0.05 mm to 0.15 mm, and
a sheet resistance of the resistive layer is 530 Ω·sq⁻¹ to 550 Ω·sq⁻¹.

2. The unit cell according to claim 1, wherein the operating bandwidth of the operating frequency is a center frequency of 5.8 GHz and a band of 5.55 GHz to 6.05 GHz, wherein an electromagnetic wave absorption rate for an incidence angle of 45° is 97% or more within the operating bandwidth range.

3. The unit cell according to claim 1, wherein the first metal layer comprises a first conductor pattern in which a width of a concentric circular ring is 0.3 mm to 0.5 mm and a radius of the concentric circular ring is 5.0 mm to 5.8 mm, and a thickness of the first metal layer is 30 μm to 40 μm.

4. The unit cell according to claim 3, wherein a horizontal length of the first intermediate layer is 20 mm to 30 mm, a vertical length of the first intermediate layer is 20 mm to 30 mm, and a thickness of the first intermediate layer is 0.1 mm to 0.3 mm.

5. The unit cell according to claim 4, wherein a horizontal length of the resistive layer is 20 mm to 30 mm, and a vertical length of the resistive layer is 20 mm to 30 mm.

6. The unit cell according to claim 5, wherein a horizontal length of the second intermediate layer is 20 mm to 30 mm, a vertical length of the second intermediate layer is 20 mm to 30 mm, and a thickness of the second intermediate layer is 0.4 mm to 0.6 mm.

7. The unit cell according to claim 6, wherein a dielectric constant of each of the first and second intermediate layers is 3.5, and a dielectric loss tangent of each of the first and second intermediate layers is 0.0027.

8. The unit cell according to claim 3, wherein a horizontal length of the second metal layer is 20 mm to 30 mm, a vertical length of the second metal layer is 20 mm to 30 mm, and a thickness of the second metal layer is 30 μm to 40 μm.

9. The unit cell according to claim 1, wherein the operating bandwidth of the operating frequency is a center frequency of 10 GHz and a band of 9.5 GHz to 10.5 GHZ, wherein an electromagnetic wave absorption rate for an incidence angle of 45° is 97% or more within the operating bandwidth range.

10. The unit cell according to claim 1, wherein the first metal layer comprises a second conductor pattern,
wherein the second conductor pattern comprises a first concentric circular ring; and a second concentric circular ring formed to surround the first concentric circular ring,
wherein a center of the second concentric circular ring coincides with a center of the first concentric circular ring,
a width of each of the first and second concentric circular rings is 0.3 mm to 0.5 mm,
a radius of the first concentric circular ring is 1.8 mm to 2.0 mm,
a radius of the second concentric circular ring is 3.2 mm to 3.4 mm, and
a thickness of the first metal layer is 30 μm to 40 μm.

11. The unit cell according to claim 10, wherein a horizontal length of the first intermediate layer is 10 mm to 20 mm, a vertical length of the first intermediate layer is 10 mm to 20 mm, and a thickness of the first intermediate layer is 0.1 mm to 0.3 mm.

12. The unit cell according to claim 11, wherein a horizontal length of the resistive layer is 10 mm to 20 mm, and a vertical length of the resistive layer is 10 mm to 20 mm.

13. The unit cell according to claim 12, wherein a horizontal length of the second intermediate layer is 10 mm to 20 mm, a vertical length of the second intermediate layer is 10 mm to 20 mm, and a thickness of the second intermediate layer is 0.4 mm to 0.6 mm.

14. The unit cell according to claim 13, wherein a dielectric constant of each of the first and second intermediate layers is 3.5, and a dielectric loss tangent of each of the first and second intermediate layers is 0.0027.

15. The unit cell according to claim 14, wherein a horizontal length of the second metal layer is 10 mm to 20 mm, a vertical length of the second metal layer is 10 mm to 20 mm, and a thickness of the second metal layer is 30 μm to 40 μm.

16. A metamaterial absorber, comprising a plurality of unit cells,
wherein the unit cells are arranged on the same plane to form a flat structure, and
each of the unit cells comprises a first metal layer comprising at least one concentric circular ring-shaped conductor pattern;
a first intermediate layer disposed on a lower surface of the first metal layer and composed of polyimide;
a resistive layer disposed on a lower surface of the first intermediate layer;
a second intermediate layer disposed on a lower surface of the resistive layer and composed of polyimide; and
a second metal layer disposed on a lower surface of the second intermediate layer,
wherein the resistive layer increases an operating bandwidth of an operating frequency,
a thickness of the resistive layer is 0.05 mm to 0.15 mm, and
a sheet resistance of the resistive layer is 530 Ω·sq⁻¹ to 550 Ω·sq⁻¹.
